(19) United States
(12) Patent Application Publication
(10) Pub. No.: US 2026/0114121 A1
(43) Pub. Date: Apr. 23, 2026

(54) LIGHT-EMITTING DEVICE, METHOD OF FABRICATING LIGHT-EMITTING DEVICE, DISPLAY DEVICE AND ELECTRONIC DEVICE

(71) Applicant: Samsung Display Co., LTD., Yongin-si (KR)

(72) Inventors: Jung Sub HWANG, Yongin-si (KR); Myoung Jin PARK, Yongin-si (KR); Jung Hwa PARK, Yongin-si (KR); Jung Ho JO, Yongin-si (KR)

(21) Appl. No.: 19/210,619

(22) Filed: May 16, 2025

(30) Foreign Application Priority Data
Oct. 21, 2024 (KR) 10-2024-0144397

(51) Int. Cl. H10K 50/16; H10K 50/115; H10K 85/60

(52) U.S. Cl. CPC H10K 50/166; H10K 50/115; H10K 85/615; H10K 85/633; H10K 85/636; H10K 85/654; H10K 85/6572; H10K 85/6574

(57) ABSTRACT

A light-emitting device includes a first electrode, a second electrode, an emission layer between the first electrode and the second electrode, and an electron transport region between the emission layer and the second electrode. The electron transport region includes a first electron transport layer on the emission layer and a second electron transport layer on the first electron transport layer. The first electron transport layer includes first particles, and the second electron transport layer includes second particles having an average particle diameter smaller than an average particle diameter of the first particles.

This application claims priority to Korean Patent Application No. 10-2024-0144397, filed on Oct. 21, 2024, and all the benefits accruing therefrom under 35 U.S.C. § 119, the content of which in its entirety is herein incorporated by reference.

### FIELD

Embodiments disclosed in the present application relate to a light-emitting device, a method of fabricating the light-emitting device, a display device, and an electronic device.

### BACKGROUND

Recently, with the development of mobile devices such as, for example, a smartphone and a tablet, and media devices such as, for example, a computer and a TV, various display devices applied to the above media devices have been developed.

A display device may include a self-luminous light-emitting device capable of emitting light by a light-emitting material to provide an image which is visually recognizable from the outside.

The light-emitting device may include transport regions of holes and electrons provided from electrodes which may be interposed between electrodes facing each other.

However, penetration and/or mixing between materials may occur in such a light-emitting material, resulting in a decrease in luminous efficiency and life-span properties.

### SUMMARY

According to an aspect of the present disclosure, provided is a light-emitting device having an improved light-emitting efficiency and an improved life-span property.

According to an aspect of the present disclosure, provided is a method of fabricating a light-emitting device having an improved light-emitting efficiency and an improved life-span property.

According to an aspect of the present disclosure, provided is a display device providing improved image quality.

According to an aspect of the present disclosure, provided is an electronic device including the light-emitting device or the display device.

A light-emitting device may include a first electrode, a second electrode, an emission layer between the first electrode and the second electrode, and an electron transport region between the emission layer and the second electrode. The electron transport region may include a first electron transport layer on the emission layer and a second electron transport layer on the first electron transport layer. The first electron transport layer may include first particles and the second electron transport layer may include second particles having an average particle diameter smaller than an average particle diameter of the first particles.

In some embodiments, the average particle diameter of the first particles may range from 5 nm to 20 nm.

In some embodiments, the average particle diameter of the first particles may range from 5 nm to 10 nm.

In some embodiments, the average particle diameter of the second particles may range from 2 nm to 4 nm.

In some embodiments, the average particle diameter of the second particles may range from 3 nm to 4 nm.

In some embodiments, the electron transport region may further include a third electron transport layer on the second electron transport layer, and the third electron transport layer may include third particles having an average particle diameter greater than the average particle diameter of the second particles.

In some embodiments, the first particles, the second particles and the third particles may include the same material.

In some embodiments, the average particle diameter of the third particles may range from 5 nm to 20 nm.

In some embodiments, the emission layer may include quantum dots.

In some embodiments, an average particle diameter of the quantum dots may range from 5 nm to 15 nm.

In some embodiments, an average particle diameter of the quantum dots may be equal to or less than the average particle diameter of the first particles.

In some embodiments, the electron transport region may further include an electron injection layer between the second electron transport layer and the second electrode.

In some embodiments, the light-emitting device may further include a hole transport region between the first electrode and the emission layer.

In some embodiments, the hole transport region may further include a hole injection layer on the first electrode, and a hole transport layer on the hole injection layer.

In some embodiments, the first particles and the second particles may each include at least one selected from the group consisting of ZnMgO, Li₂O, BaO, LiF, NaCl, CsF, RbCl, RbI, CuI, KI, a metal acetate, a metal benzoate, an anthracene compound, Alq3 (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), Bebq2 (bis(10-hydroxybenzo[h]quinolinato)beryllium), ADN (9,10-di(naphthalene-2-yl)anthracene) and BmPyPhB (1,3-bis[3,5-di(pyridin-3-yl)phenyl]benzene).

A display device may include a base substrate, a circuit layer on the base substrate, and a light-emitting device electrically connected to the circuit layer. The light-emitting device may include a first electrode, a second electrode, an emission layer between the first electrode and the second electrode, and an electron transport region between the emission layer and the second electrode. The electron transport region may include a first electron transport layer on the emission layer and a second electron transport layer on the first electron transport layer. The first electron transport layer may include first particles and the second electron transport layer may include second particles having an average particle diameter smaller than an average particle diameter of the first particles.

In some embodiments, the emission layer may include quantum dots, and the circuit layer may include a transistor connected to the first electrode of the light-emitting device.

An electronic device may include the above-described display device, a memory, and a processor for executing data included in the memory in association with controlling an operation of the display device.

In a method of fabricating a light-emitting device, an emission layer may be formed on a first electrode. The method may include forming a first electron transport layer including first particles may be formed on the emission layer by an inkjet printing. The method may include forming a second electron transport layer on the first electron transport layer by an inkjet printing, wherein the second electron transport layer includes second particles that have an average particle diameter smaller than an average particle diameter of the first particles. The method may include forming a second electrode on the second electron transport layer.

In some embodiments, the method may include forming a third electron transport layer between the second electron transport layer and the second electrode. The third electron transport layer may include third particles that have an average particle diameter greater than the average particle diameter of the second particles.

According to embodiments, an electron transport region included in a light-emitting device may include a first electron transport layer disposed on an emission layer and including first particles, and a second electron transport layer disposed on the first electron transport layer and including second particles. An average particle diameter D50 of the second particles may be less than an average particle diameter D50 of the first particles. Accordingly, the first particles having a relatively large average particle diameter D50 may suppress penetration and/or diffusion of the second particles into the emission layer. Thus, luminous efficiency, color sharpness and life-span properties of the light-emitting device may be improved.

### BRIEF DESCRIPTION OF THE DRAWINGS

FIG. 1 is a schematic cross-sectional view illustrating a light-emitting device according to embodiments.

FIG. 2 is a schematic cross-sectional view illustrating a light-emitting device according to embodiments.

FIG. 3 is a schematic cross-sectional view illustrating a light-emitting device according to embodiments.

FIG. 4 is a schematic cross-sectional view illustrating a light-emitting device according to embodiments.

FIG. 5 is a schematic cross-sectional view illustrating a light-emitting device according to embodiments.

FIG. 6 is a schematic plan view illustrating a display device according to embodiments.

FIG. 7 is a schematic cross-sectional view illustrating a display device according to embodiments.

FIG. 8 is a schematic cross-sectional view illustrating a display device according to embodiments.

FIG. 9 is a block diagram of an electronic device in accordance with an embodiment.

FIG. 10 is a schematic diagram of an electronic device in accordance with various embodiments.

### DETAILED DESCRIPTION

According to embodiments of the present disclosure, a light-emitting device including a first electron transport layer that includes a first particle, and a second electron transport layer that includes a second particle is provided. In some aspects, a display device including the light-emitting device is provided.

Hereinafter, embodiments of the present invention will be described in more detail with reference to the attached drawings. The same reference numerals can 1 be used for indicating the same elements in the drawings, and repeated descriptions of the same elements can be omitted. Embodiments disclosed in the attached drawings are examples, and is to be understood to include all modifications, equivalents and substitutes included in the spirit and technical scope of the present invention.

The terms “on”, “connected”, “coupled,” and the like, used herein refer to a direct placement/connection/combination, and also refers to a case where another element is interposed two different elements.

The terms “first”, “second”, “below”, “below”, “above,” “above,” and the like, are used in a relative sense to distinguish different elements or positions, and do not specify an absolute position or an absolute order.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

As used herein, the terms “average particle diameter (D50),” “average particle diameter,” or “D50” may refer to a particle diameter for which a volume cumulative percentage corresponds to 50% in a particle size distribution based on a particle volume.

In the present specification, the term “substituted or unsubstituted” may refer to being substituted or unsubstituted by one or more substituent selected from the group consisting of, e.g., a deuterium atom, a halogen atom, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group (e.g., a C₁-C₆₀, C₁-C₃₀ or C₁-C₁₀ alkyl group), an alkenyl group (e.g., a C₂-C₆₀, C₂-C₃₀ or C₂-C₁₀ alkenyl group), an alkynyl group (e.g., a C₂-C₆₀, C₂-C₃₀ or C₂-C₁₀ alkynyl group), an alkoxy group (e.g., a C₁-C₆₀, C₁-C₁₀ alkoxy group), a hydrocarbon ring group, an aryl group (e.g., a C₆-C₆₀ aryl group), and a heterocyclic group (e.g., a C₁-C₆₀ heterocyclic group). For example, the term “substituted alkyl group” may refer to a group in which at least one of hydrogen atoms of the alkyl group is substituted with the above-described substituent, and thus the substituent is further bonded to a carbon atom of the alkyl group.

The substituent may include a combination selected from the above-described groups. For example, at least one of hydrogen atoms of the alkyl group, the aryl group, or other above-described groups, included as the substituent may be substituted with a deuterium atom, a halogen atom, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group, an alkenyl group, an alkynyl group, a hydrocarbon ring group, an aryl group, or a heterocyclic group.

In the substituents, a multivalent substituent such as, for example, the amino group, the phosphine sulfide group, the phosphine oxide group, the sulfinyl group, the sulfonyl group, the oxy group, the carbonyl group, the ester group, etc., may be substituted with a C₁-C₁₀ alkyl group, a C₁-C₁₀ alkenyl group, a C₁-C₁₀ alkynyl group, or a C₆-C₁₀ aryl group.

The term “substituted or unsubstituted Cₐ-C_{b} Y group” as used herein, refer to the number of carbon atoms of the Y group in an unsubstituted state, and may not include carbon atoms of the substituent.

An alkyl group refers to a monovalent hydrocarbon group in which one hydrogen atom is removed from a linear or branched hydrocarbon group. For example, the alkyl group may include a methyl group, an ethyl group, a propyl group, a sec-butyl group, a tert-butyl group, an iso-butyl group, a pentyl group, a neopentyl group, a 2-ethyl butyl group, a 3,3-dimethyl butyl group, a hexyl group, a heptyl group, an octyl group, etc.

An alkylene group may refer to a divalent hydrocarbon group in which two hydrogen atoms are removed from a linear or branched hydrocarbon group.

An alkenyl group may have the same skeleton as the skeleton of the alkyl group, and may refer to a monovalent hydrocarbon group in which at least one of bonds between carbon atoms has a double bond. An alkenylene group may refer to a divalent hydrocarbon group in which one hydrogen atom is further removed from the alkenyl group.

An alkynyl group may have the same skeleton as the skeleton of the alkyl group, and may refer to a monovalent hydrocarbon group in which at least one of bonds between carbon atoms has a triple bond. The alkynylene group may refer to a divalent hydrocarbon group in which one hydrogen atom is further removed from the alkynyl group.

The aryl group may refer to a monovalent hydrocarbon group in which one hydrogen atom is removed from a hydrocarbon group having an aromatic structure. The aryl group may include a group in which a plurality of aromatic rings are directly connected, such as, for example, a biphenyl group. The aryl group may include, e.g., a phenyl group, a naphthyl group, an anthracenyl group, a phenantrenyl group, a pyrenyl group, a fluorenyl group, a tetracenyl group, a biphenyl group, a terphenyl group, a quarter phenyl group, a chrysenyl group, etc.

A group in which two or more aryl rings are condensed/linked to each other by an alicyclic hydrocarbon ring, such as, for example, the fluorenyl group, can be included in the category of the aryl group.

For example, the biphenyl group may be interpreted as an aryl group or a phenyl group substituted with a phenyl group.

An arylene group may refer to a divalent hydrocarbon group in which two hydrogen atoms are removed from the aryl group.

The heteroaryl group may refer to a monovalent group having an aromatic structure and including at least one heteroatom such as, for example, B, O, P, S, and Si among ring-forming atoms. The heteroarylene group may refer to a divalent group having an aromatic structure and including at least one heteroatom such as, for example, B, O, P, S, and Si among ring-forming atoms. In an example in which the heteroaryl group or the heteroarylene group includes two or more heteroatoms, the two or more heteroatoms may be the same or different from each other.

A structure in which two or more aryl rings are condensed/linked by a non-aromatic heterocyclic ring, such as, for example, a carbazole group can also be included in the category of the heteroaryl group.

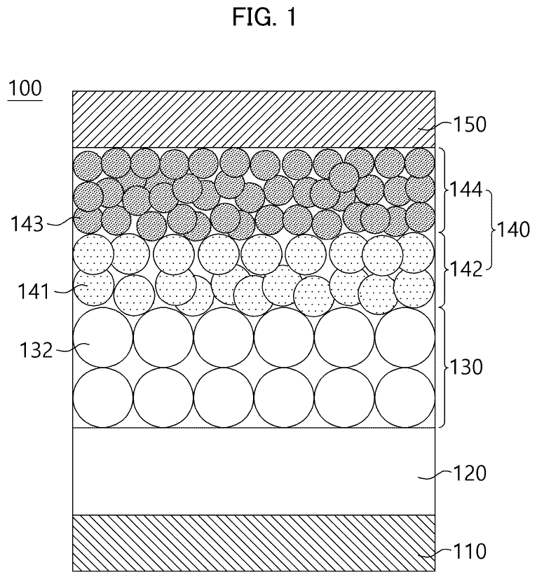

FIG. 1 is a schematic cross-sectional view illustrating a light-emitting device according to embodiments.

Referring to FIG. 1, a light-emitting device 100 may include a first electrode 110, an emission layer 130, an electron transport region 140 and a second electrode 150, which are sequentially stacked.

In embodiments, a hole transport region 120 may be further disposed between the first electrode 110 and the emission layer 130.

The first electrode 110 may be an anode or a cathode. In some embodiments, the first electrode 110 may serve as an anode and may serve as a pixel electrode. In this case, the first electrode 110 may include a high work function conductive material which promotes hole injection.

The first electrode 110 may be provided as a transmissive electrode. The first electrode 110 may include a transparent conductive oxide such as, for example, indium tin oxide (ITO), indium zinc oxide (IZO), zinc oxide (ZnO), indium tin oxide (ITZO), or the like.

The first electrode 110 may be provided as a translucent electrode or a reflective electrode. The first electrode 110 may include a metal selected from Ag, Mg, Cu, Al, Pt, Pd, Au, Ni, Nd, Ir, Cr, Li, Ca, LiF, Mo, Ti, W, In, Sn and Zn, or an alloy of two or more therefrom. For example, the first electrode 110 may include Li, Ca, LiF/Ca (a stacked structure of LiF and Ca), LiF/Al (a stacked structure of LiF and Al), a mixture of Ag and Mg.

The first electrode 110 may have a single-layered structure or a multi-layered structure. For example, the first electrode 110 may have a triple-layered structure of ITO/Ag/ITO.

A thickness of the first electrode 110 may range from about 700 Å to about 10,000 Å or from about 1,000 Å to about 3,000 Å.

The second electrode 150 may serve as a cathode or an anode. In some embodiments, the second electrode 150 may serve as an electron injection electrode or a cathode. The second electrode 150 may include a metal, an alloy, an electrically conductive compound, or other material, having a low work function.

For example, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, etc. They may be used alone or in a combination of two or more therefrom.

The second electrode 150 may be provided as a transmissive electrode, a translucent electrode or a reflective electrode. The second electrode 150 may have a single-layered structure or a multi-layered structure.

The emission layer 130 may be provided as a display layer of the light-emitting device 100.

In embodiments, the emission layer 130 may include quantum dots 132.

The quantum dots 132 may include a material that emits light when stimulated by light or an electric field. For example, the quantum dots 132 may receive energy from an outside and reach an excited state, and may emit an energy (e.g., a light) according to an energy band gap of the quantum dots 132.

For example, the quantum dots 132 may include a group II-VI compound, a group III-V compound, a group IV-VI compound, a group IV element or a compound including the same, and a mixture thereof. These may be used alone or in a combination of two or more therefrom.

The group II-VI compound may be selected from a group consisting of a binary compound selected from CdS, CdSe, CdTe, ZnS, ZnSe, ZnTe, ZnO, HgS, HgSe, HgTe, MgSe, MgS, and a mixture thereof; a ternary compound selected from CdSeS, CdSeTe, CdSTe, CdZnS, CdZnSe, CdZnTe, CdHgS, CdHgSe, CdHgTe, ZnSeS, ZnSeTe, ZnSTe, HgSeS, HgSeTe, HgSTe, HgZnS, HgZnSe, HgZnTe, and a mixture thereof; and a quaternary compound selected from CdZnSeS, CdZnSeTe, CdZnSTe, CdHgSeS, CdHgSeTe, CdHgSTe, HgZnSeS, HgZnSeTe, HgZnSTe, and a mixture thereof.

The group III-V compound may be selected from a group consisting of a binary compound selected from GaN, GaP, GaAs, GaSb, AlN, AlP, AlAs, AlSb, InN, InP, InAs, InSb, and a mixture thereof; a ternary compound selected from GaNP, GaNAs, GaNSb, GaPAs, GaPSb, AlNP, AlNAs, AlNSb, AlPAs, AlPSb, InNP, InNAs, InNSb, InPAs, InPSb, GaAlNP, and a mixture thereof; and a quaternary compound selected from GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

The group IV-VI compound may be selected from a group consisting of a binary compound selected from SnS, SnSe, SnTe, PbS, PbSe, PbTe, and a mixture thereof; a ternary compound selected from SnSeS, SnSeTe, SnSTe, PbSeS, PbSeTe, PbSTe, SnPbS, SnPbSe, SnPbTe, and a mixture thereof; and a quaternary compound selected from SnPbSSe, SnPbSeTe, SnPbSTe, and a mixture thereof.

The group IV element or a compound including the same may include Si, Ge, SiC, SiGe, and a mixture thereof.

In some embodiments, the quantum dots 132 may have a homogeneous single structure, a core-shell structure, a gradient structure, or a mixed structure thereof.

In some embodiments, the quantum dots 132 may have a core-shell structure. A core may be a portion where a light emission is substantially implemented. A shell may prevent oxidation of the core and reduce a trap energy level on at a surface of the core, thereby improving stability and efficiency of the core. The shell may include an inorganic oxide or a semiconductor compound. The semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like.

For example, a color of the emitted light may be adjusted according to a particle size of the quantum dots 132. The quantum dots 132 may be classified into blue quantum dots, red quantum dots, green quantum dots, or the like.

In some embodiments, the quantum dots 132 may emit a blue light, a red light or a green light. Accordingly, a separate color filter or a backlight may not be included in the display device. Thus, a thickness of the light-emitting device 100 or the display device/electronic device to which the light-emitting device 100 is applied may be reduced and a production cost may be reduced.

In some embodiments, tan average particle diameter (D50) of the quantum dots 132 may range from 5 nm to 15 nm, and in another embodiment, may range from 8 nm to 12 nm. In the described ranges, luminous efficiency and color sharpness may be improved.

In some embodiments, the emission layer 130 may include a host material excited by holes and electrons, and a dopant material for increasing luminous efficiency through absorption and emission of energy.

In an embodiment, the emission layer 130 may be independently patterned for each of a red light-emitting device, a green light-emitting device, and a blue light-emitting device to generate a different colored light for each light-emitting device. For example, the emission layer 130 may be patterned as a red emission layer, a green emission layer and a blue emission corresponding to each light-emitting device.

In an embodiment, the emission layer 130 may not be patterned for each light-emitting device and may be commonly provided to a plurality of the light-emitting devices. For example, the emission layer 130 may emit a white light, and a color of each device may be implemented through a color filter.

The host material may include a host for a phosphorescent device, a fluorescent host, or a combination thereof. For example, the host material may include BCPDS (bis(4-(9H-carbazol-9-yl) phenyl) diphenylsilane), POPCPA ((4-(1-(4-(diphenylamino) phenyl) cyclohexyl) phenyl) diphenyl-phosphine oxide), DPEPO (bis[2-(diphenylphosphino)phenyl]ether oxide), mCBP (3,3′-di(9H-carbazol-9-yl)-1,1′-biphenyl), CBP (4,4′-bis(N-carbazolyl)-1,1′-biphenyl), mCP (1,3-bis(carbazol-9-yl)benzene), PPF (2,8-bis(diphenylphosphoryl) dibenzo[b,d]furan), TCTA (4,4′,4″-tris(carbazol-9-yl)-triphenylamine), TPBi (1,3,5-tris(1-phenyl-1H-benzo[d]imidazole-2-yl)benzene), Alq3 (tris(8-hydroxyquinolino) aluminum), ADN (9,10-di(naphthalene-2-yl)anthracene), TBADN (2-tert-butyl-9,10-di(naphth-2-yl)anthracene), DSA (distyrylarylene), CDBP (4,4′-bis(9-carbazolyl)-2,2′-dimethyl-biphenyl), MADN (2-methyl-9,10-bis(naphthalen-2-yl)anthracene), CP1 (hexaphenyl cyclotriphosphazene), UGH2 (1,4-bis(triphenylsilyl)benzene), DPSiO₃ (hexaphenylcyclotrisiloxane), DPSiO4 (octaphenylcyclotetrasiloxane), etc.

The dopant material may include a phosphorescent dopant, a fluorescent dopant, or a combination thereof. For example, the dopant material may include a metal complex containing iridium (Ir), platinum (Pt), osmium (Os), gold (Au), titanium (Ti), zirconium (Zr), hafnium (Hf), europium (Eu), terbium (Tb) or thulium (Tm); or BCzVB (1,4-bis[2-(3-N-ethylcarbazoryl)vinyl]benzene), DPAVB (4-(di-p-tolylamino)-4′-[(di-p-tolylamino)styryl]stilbene), N-BDAVBi (N-(4-((E)-2-(6-((E)-4-(diphenylamino)styryl)naphthalen-2-yl)vinyl)phenyl)-N-phenylbenzenamine), DPAVBi (4,4′-bis[2-(4-(N,N-diphenylamino)phenyl)vinyl]biphenyl), TBP (2,5,8,11-Tetra-t-butylperylene) or a combination thereof.

In an embodiment, a thickness of the emission layer 130 may range from about 100 Å to about 1000 Å, from about 100 Å to about 800 Å, from about 200 Å to about 800 Å, or from about 200 Å to about 600 Å. In the above range, luminous efficiency and life-span of the light-emitting device 100 may be further improved.

In embodiments, the electron transport region 140 may include a first electron transport layer 142 that may be disposed on the emission layer 130 and may include first particles 141, and a second electron transport layer 144 that may be disposed on the first electron transport layer 142 and may include second particles 143.

In an embodiment, the first electron transport layer 142 may be directly disposed on the emission layer 130.

In an embodiment, the second electron transport layer 144 may be directly disposed on the first electron transport layer 142.

An average particle diameter D50 of the second particles 143 may be less than D50 of the first particles 141. Accordingly, the first particles 141 having the relatively large D50 may suppress penetration and/or diffusion of the second particles 143 into the emission layer 130. Accordingly, luminous efficiency, color sharpness and life-span properties of the light-emitting device 100 may be improved.

In an example in which the quantum dots 132 are provided as a light-emitting material of the emission layer 130, the emission layer 130 and the electron transport region 140 may be formed by an inkjet printing process. In this case, some of the particles included in the electron transport region 140 may penetrate and/or diffuse into the emission layer 130 along an ink drop to degrade luminous efficiency and life-span properties.

According to embodiments of the present invention, the first particles 141 having the relatively large D50 may function as a barrier between the emission layer 130 and the electron transport region 140, and thus the above-described interlayer penetration and/or diffusion may be suppressed. Accordingly, luminous efficiency and life-span properties of the light-emitting device 100 may be improved.

In an embodiment, a D50 of the quantum dots 132 may be greater than or equal to the D50 of the first particles 141. In this case, the D50 of the first particles 141 may be sufficiently large such that the first particles 141 may suppress the described penetration and/or diffusion between the emission layer 130 and the electron transport region 140.

In an embodiment, the D50 of the quantum dots 132 may be equal to or less than the D50 of the first particles 141. Accordingly, the penetration and/or diffusion may be further physically prevented.

In some embodiments, the D50 of the first particles 141 may range from 5 nm to 20 nm, and in another embodiment, may range from 5 nm to 10 nm. In the described ranges, penetration and/or diffusion of the second particles 143 into the light emitting layer 130 may be further prevented.

In some embodiments, the D50 of the second particles 143 may range from 2 nm to 4 nm, and in another embodiment, may range from 3 nm to 4 nm. In the described ranges, electron mobility from the second electrode 150 may be maintained or improved.

Accordingly, luminous efficiency of the light-emitting device 100 may be further improved.

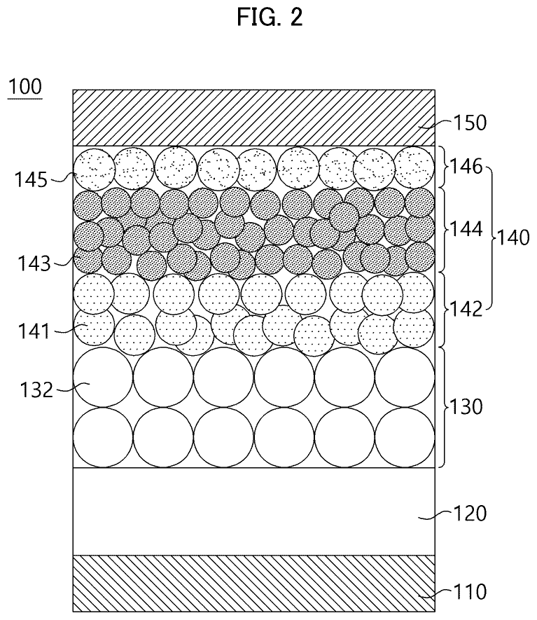

FIG. 2 is a schematic cross-sectional view illustrating a light-emitting device according to embodiments.

Referring to FIG. 2, the electron transport region 140 may further include a third electron transport layer 146 disposed on the second electron transport layer 144 and including third particles 145.

In an embodiment, the third electron transport layer 146 may be directly disposed on the second electron transport layer 144.

In an embodiment, the third electron transport layer 146 may be interposed between the second electron transport layer 144 and the second electrode 150.

A D50 of the third particles 145 may be greater than a D50 of the second particles 143. Thus, penetration and/or diffusion of the second particles 143 into the second electrode 150 may be suppressed. Thus, life-span properties and luminous efficiency of the light-emitting device 100 may be further improved.

In some embodiments, the D50 of the third particles 145 may range from 5 nm to 20 nm, and in another embodiment, may range from 5 nm to 10 nm. In the described ranges, penetration and/or diffusion of the particles included in the electron transport region 140 into the second electrode 150 may be further prevented.

In embodiments, the hole transport region 120 may be disposed between the first electrode 110 and the emission layer 130. The hole transport region 120 may have a single-layered or a multi-layered structure including a plurality of layers of different materials.

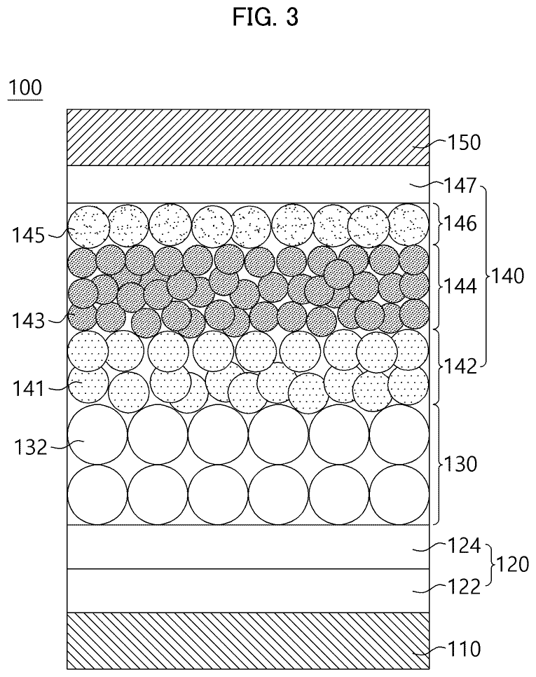

FIG. 3 is a schematic cross-sectional view illustrating a light-emitting device according to embodiments.

Referring to FIG. 3, the electron transport region 140 may further include an electron injection layer 147 disposed between the second electron transport layer 144 and the second electrode 150. In some embodiments, the electron injection layer 147 may be interposed between the third electron transport layer 146 and the second electrode 150.

The hole transport region 120 may include a hole injection layer 122 disposed on the first electrode 110, and a hole transport layer 124 disposed on the hole injection layer 122. For example, the hole injection layer 122 and the hole transport layer 124 may be sequentially stacked in a direction from the first electrode 110 to the emission layer 130.

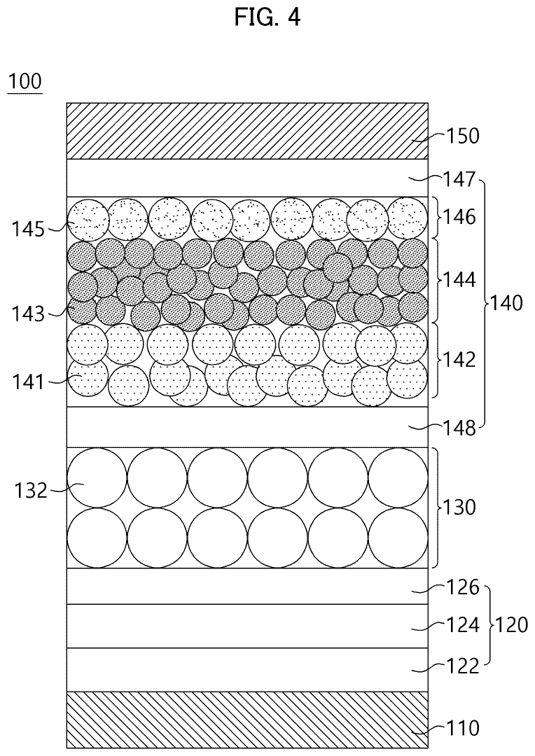

FIG. 4 is a schematic cross-sectional view illustrating a light-emitting device according to embodiments.

Referring to FIG. 4, the electron transport region 140 may further include a hole blocking layer 148 disposed between the emission layer 130 and the first electron transport layer 142. Injection of a hole from the hole transport region 120 may be suppressed or blocked by the hole blocking layer 148. Accordingly, emission energy and luminous efficiency of the emission layer 130 may be further improved.

In some embodiments, penetration or diffusion of the second particles 143 into the hole blocking layer 148 and/or the emission layer 130 may be suppressed by the first electron transport layer 142. Accordingly, life-span and luminous properties of the light-emitting device 100 may be improved while enhancing hole barrier performance of the hole blocking layer 148.

For example, the electron transport region 140 may include a compound represented by Chemical Formula ET below.

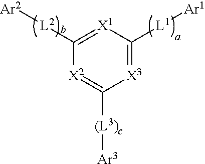

In Chemical Formula ET, at least one of X¹ to X³ may be N and remainders may each independently be CRₐ. Rₐ may be a hydrogen atom, a deuterium atom, a substituted or unsubstituted C₁-C₂₀ alkyl group, a substituted or unsubstituted C₆-C₆₀ aryl group, or a substituted or unsubstituted C₂-C₆₀ heteroaryl group.

When one of X¹ to X³ is N, the compound represented by Chemical Formula ET may include a pyridine group. In an example in which two of X¹ to X³ are N, the compound represented by Chemical Formula ET may include a pyrimidine group. In an example in which all of X¹ to X³ are N, the compound represented by Chemical Formula ET may include a triazine group.

a, b and c may each independently be an integer of 0 to 10. L¹ to L³ may each independently be a direct linkage, a substituted or unsubstituted C₆-C₃₀ arylene group, or a substituted or unsubstituted C₂-C³⁰ heteroarylene group.

When a, b and c is an integer of 2 or more, a plurality of L¹s, L²s, or L³s are directly linked, e.g., by carbon atoms of each aryl ring (e.g., sp2 carbons), and may each independently be a substituted or unsubstituted C₆-C₃₀ arylene group, or a substituted or unsubstituted C₂-C₃₀ heteroarylene group.

Ar¹ to Ar³ may each independently be a hydrogen atom, a deuterium atom, a substituted or unsubstituted C₁-C₂₀ alkyl group, a substituted or unsubstituted C₆-C₃₀ aryl group, or a substituted or unsubstituted C₂-C₃₀ heteroaryl group. For example, Ar¹ to Ar³ may each independently be a substituted or unsubstituted phenyl group, a substituted or unsubstituted carbazole group, or a substituted or unsubstituted fluorene group.

Non-limiting examples of the compound represented by Chemical formula ET are as follows.

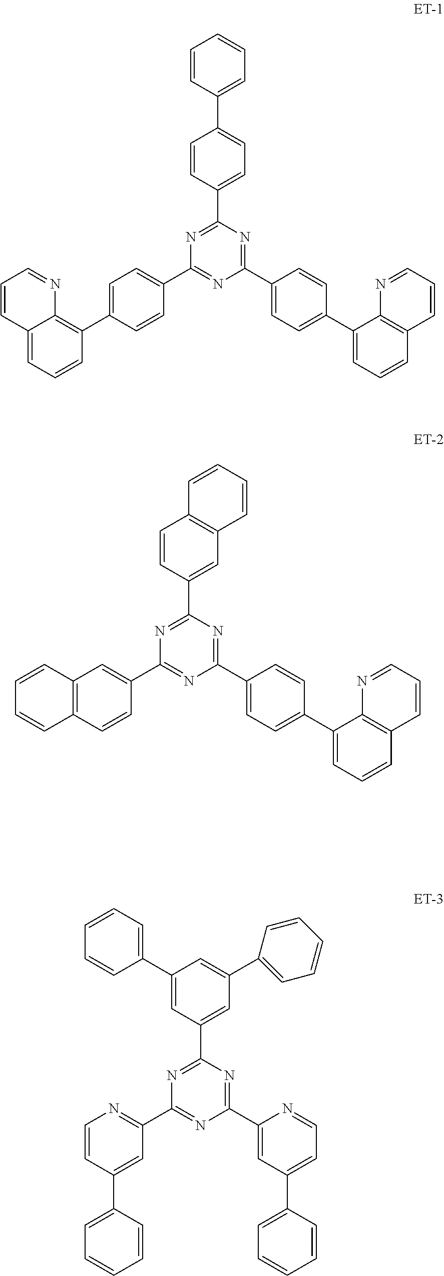 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; c1ccc(-c2cc(-c3ccccc3)cc(-c3nc(-c4cc(-c5ccccc5)ccn4)nc(-c4cc(-c5ccccc5)ccn4)n3)c2)cc1]

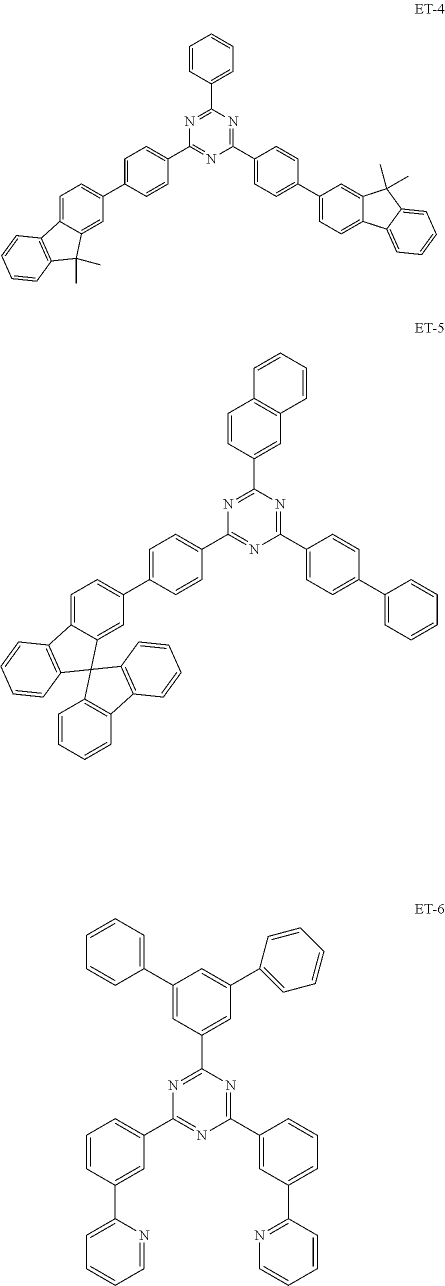 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3nc(-c4ccc(-c5ccc6c(c5)C5(c7ccccc7-c7ccccc75)c5ccccc5-6)cc4)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

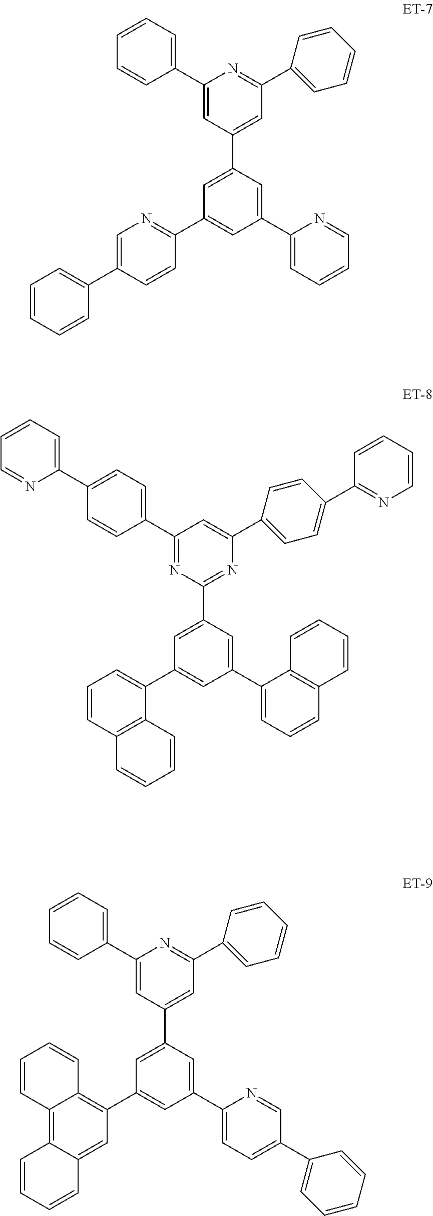 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

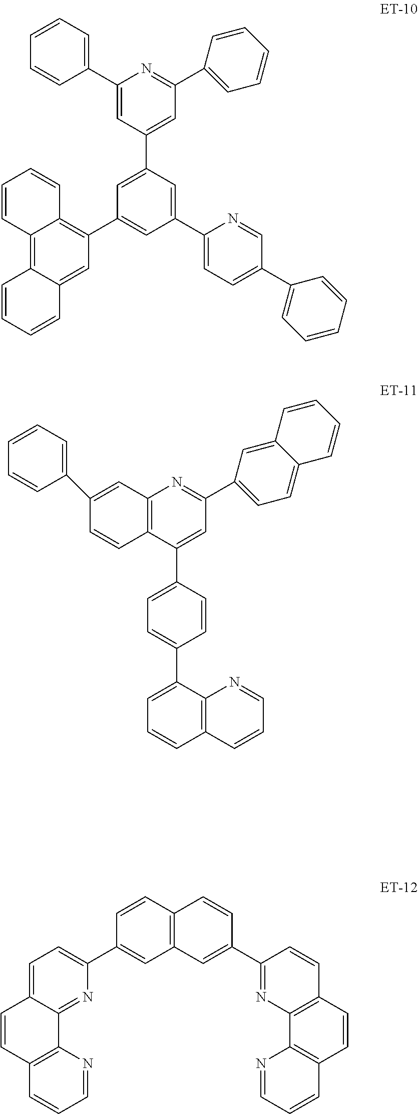 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

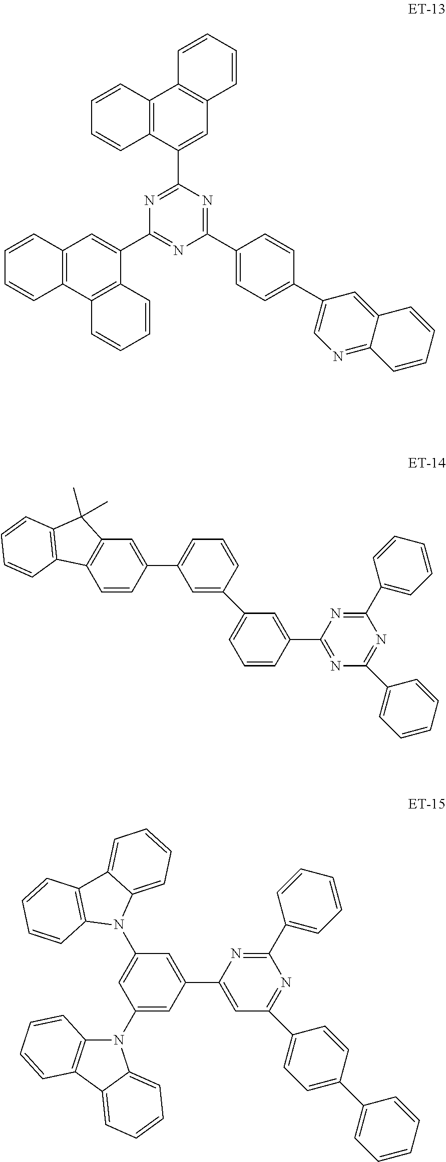 [SMILES: c1ccc2ncc(-c3ccc(-c4nc(-c5cc6ccccc6c6ccccc56)nc(-c5cc6ccccc6c6ccccc56)n4)cc3)cc2c1 ; CC1(C)c2ccccc2-c2ccc(-c3cccc(-c4cccc(-c5nc(-c6ccccc6)nc(-c6ccccc6)n5)c4)c3)cc21 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

For example, the electron transport region 140 may include an anthracene compound, Alq3 (tris(8-hydroxyquinolinato) aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), Bebq2 (bis(10-hydroxybenzo[h]quinolinato)beryllium), ADN (9,10-di(naphthalene-2-yl)anthracene), BmPyPhB (1,3-bis[3,5-di(pyridin-3-yl)phenyl]benzene), etc. These may be used alone or in combination of two or more therefrom.

The above-described material may be included in at least one layer of the electron injection layer 147, the first electron transport layer 142, the second electron transport layer 144, the third electron transport layer 146, and the hole blocking layer 148.

The electron transport region 140 may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a combination thereof. In an embodiment, the above-described material may be included in the electron injection layer 147.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound and the rare earth metal-containing compound may include an oxide, a halide (e.g., a fluoride, a chloride, a bromide, an iodide, or other halide), a telluride, or a combination thereof of the alkali metal, the alkaline earth metal and the rare earth metal, respectively.

The alkali metal complex, the alkaline earth metal complex and the rare earth metal complex may include a metal ion of the above-described alkali metal, the alkaline earth metal or the rare earth metal, and a ligand bonded to the metal ion. The ligand may include, e.g., hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or a combination thereof.

In some embodiments, the first particles 141, the second particles 143 and/or the third particles 145 may include ZnMgO, Li₂O, BaO, LiF, NaCl, CsF, RbCl, RbI, CuI, KI, a metal acetate, a metal benzoate, an anthracene compound, Alq3 (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), Bebq2 (bis(10-hydroxybenzo[h]quinolinato)beryllium), ADN (9,10-di(naphthalene-2-yl)anthracene), BmPyPhB (1,3-bis[3,5-di(pyridin-3-yl)phenyl]benzene), etc. These may be used alone or in a combination of two or more therefrom

In an embodiment, the first particles 141, the second particles 143 and/or the third particles 145 may include ZnMgO.

A thickness of the electron transport region 140 may range from about 100 Å to about 1,000 Å, e.g., from about 150 Å to about 500 Å. In an example in which the electron transport region 140 includes the electron injection layer 147, the first electron transport layer 142, the second electron transport layer 144, and the third electron transport layer 146, a thickness of the electron injection layer 147 may range from about 1 Å to about 100 Å, from about 1 Å to about 90 Å, or from about 5 Å to about 50 Å, and a sum of the thicknesses of the first electron transport layer 142, the second electron transport layer 144, and the third electron transport layer 146 may range from about 10 Å to about 900 Å, from about 10 Å to about 500 Å, or from about 100 Å to about 400 Å.

In the above thickness range, electron injection and electron transport properties may be further improved without excessive increase in a driving voltage, and stability of the electron transport region 140 may be improved.

Each layer of the electron transport region 140 may be formed by a process such as, for example, a vacuum deposition, a spin coating, an inkjet printing, a laser printing, a casting, a laser thermal transfer, or the like.

In an embodiment, each layer of the electron transport region 140 may be formed by an inkjet printing. For example, the first electron transport layer 142, the second electron transport layer 144, and/or the third electron transport layer 146 may be formed by an inkjet printing.

In an example in which the quantum dots 132 are used as a light-emitting material of the emission layer 130, fabrication of a large-area emission pattern may be performed in a short period using the inkjet printing. As described herein, a plurality of layers (i.e., the first electron transport layer 142, the second electron transport layer 144, the third electron transport layer 146) including particles having different D50s may be arranged through the inkjet printing and may suppress interlayer penetration and/or diffusion as described herein. Thus, luminous efficiency and life-span properties may be improved while enhancing production efficiency.

As illustrated in FIG. 4, the hole transport region 120 may include the hole injection layer 122, the hole transport layer 124 and an electron blocking layer 126, which are sequentially stacked from the first electrode 110. Electron transfer from the electron transport region 140 to the hole transport region 120 may be blocked by the electron blocking layer 126. Accordingly, generation of excitons in the emission layer 130 may be increased, and luminous efficiency may be further increased.

For example, the hole transport region 120 may include a compound represented by Chemical Formula HT below.

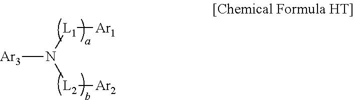

In Chemical Formula HT, L₁ and L₂ may each independently be a direct linkage, a substituted or unsubstituted C₆-C₃₀ arylene group, or a substituted or unsubstituted C₂-C₃₀ heteroarylene group.

a and b may each independently be an integer of 0 to 10. In an example in which a or b is an integer greater than or equal to 2, a plurality of L₁ and a plurality of L₂ are directly connected, e.g., by carbon atoms of each aryl ring (e.g., sp2 carbons), and may each independently be a substituted or unsubstituted C₆-C₃₀ arylene group, or a substituted or unsubstituted C₂-C₃₀ heteroarylene group.

Ar₁ and Ar₂ may each independently a substituted or unsubstituted C₆-C₃₀ aryl group, or a substituted or unsubstituted C₂-C₃₀ heteroaryl group, and Ar₃ is a substituted or unsubstituted C₆-C₃₀ aryl group.

In an embodiment, the compound represented by Chemical Formula HT may be a monoamine compound. In an embodiment, the compound represented by Chemical Formula HT may be a diamine compound in which at least one of Ar₁ to Ar₃ includes an amine group as a substituent.

In some embodiments, the compound represented by Chemical Formula HT may be a carbazole-based compound containing a substituted or unsubstituted carbazole group in at least one of Ar₁ and Ar₂, or a fluorene-based compound containing a substituted or unsubstituted fluorene group in at least one of Ar₁ and Ar₂.

Non-limiting examples of the compound represented by the formula HT are as follows.

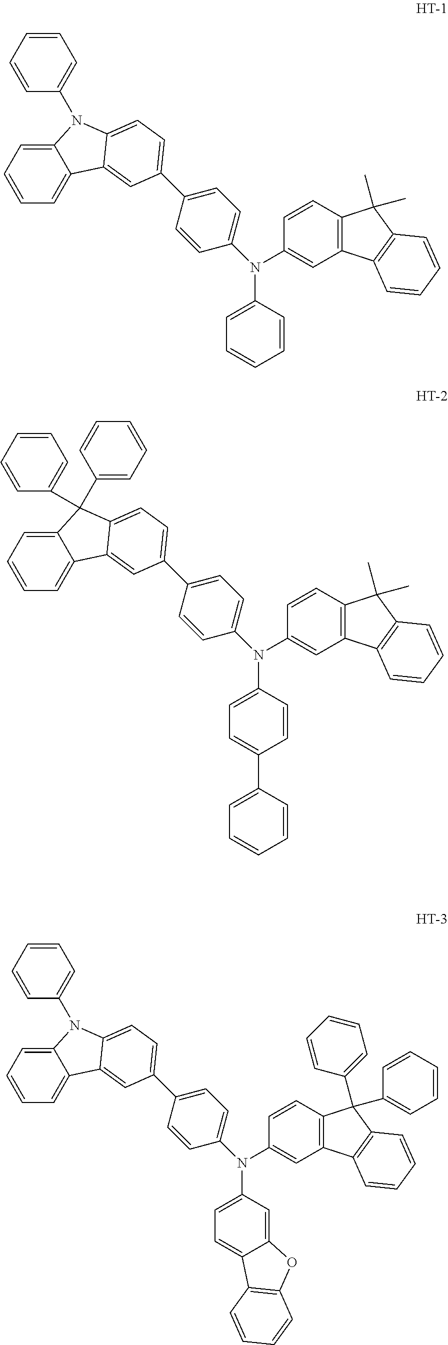 [SMILES: CC1(C)c2ccccc2-c2cc(N(c3ccccc3)c3ccc(-c4ccc5c(c4)c4ccccc4n5-c4ccccc4)cc3)ccc21 ; CC1(C)c2ccccc2-c2cc(N(c3ccc(-c4ccccc4)cc3)c3ccc(-c4ccc5c(c4)-c4ccccc4C5(c4ccccc4)c4ccccc4)cc3)ccc21 ; c1ccc(-n2c3ccccc3c3cc(-c4ccc(N(c5ccc6c(c5)-c5ccccc5C6(c5ccccc5)c5ccccc5)c5ccc6c(c5)oc5ccccc56)cc4)ccc32)cc1]

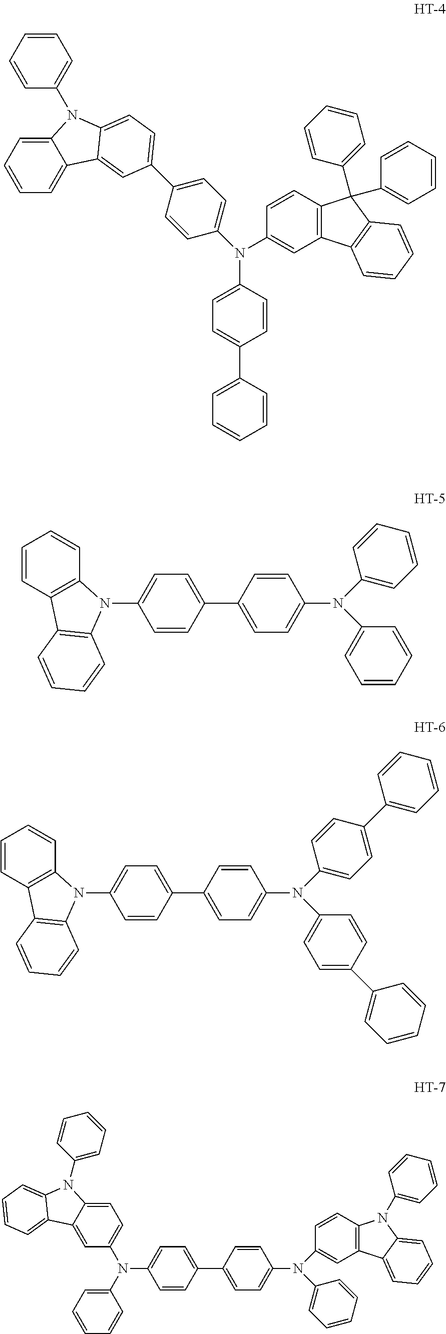 [SMILES: c1ccc(-c2ccc(N(c3ccc(-c4ccc5c(c4)c4ccccc4n5-c4ccccc4)cc3)c3ccc4c(c3)-c3ccccc3C4(c3ccccc3)c3ccccc3)cc2)cc1 ; c1ccc(N(c2ccccc2)c2ccc(-c3ccc(-n4c5ccccc5c5ccccc54)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

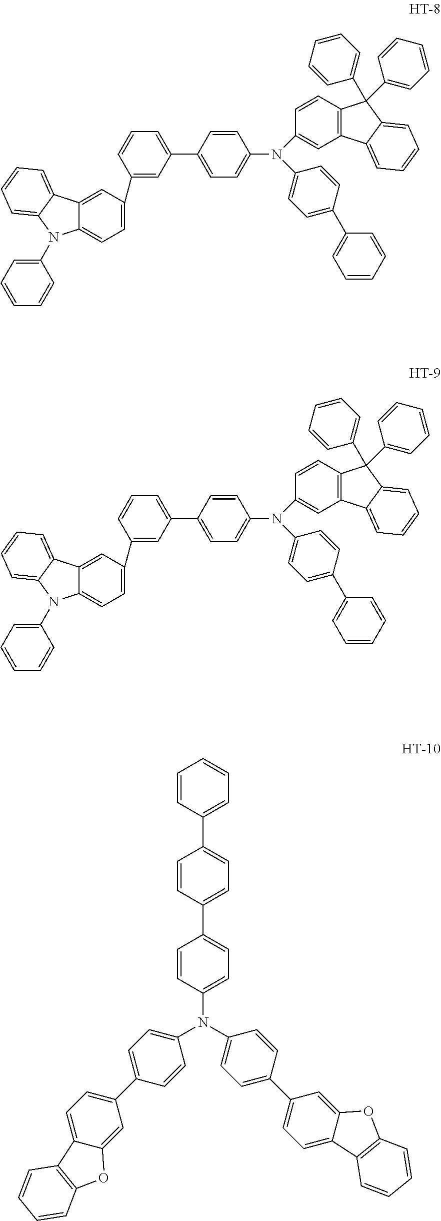 [SMILES: c1ccc(-c2ccc(N(c3ccc(-c4cccc(-c5ccc6c(c5)c5ccccc5n6-c5ccccc5)c4)cc3)c3ccc4c(c3)-c3ccccc3C4(c3ccccc3)c3ccccc3)cc2)cc1 ; c1ccc(-c2ccc(N(c3ccc(-c4cccc(-c5ccc6c(c5)c5ccccc5n6-c5ccccc5)c4)cc3)c3ccc4c(c3)-c3ccccc3C4(c3ccccc3)c3ccccc3)cc2)cc1 ; c1ccc(-c2ccc(-c3ccc(N(c4ccc(-c5ccc6c(c5)oc5ccccc56)cc4)c4ccc(-c5ccc6c(c5)oc5ccccc56)cc4)cc3)cc2)cc1]

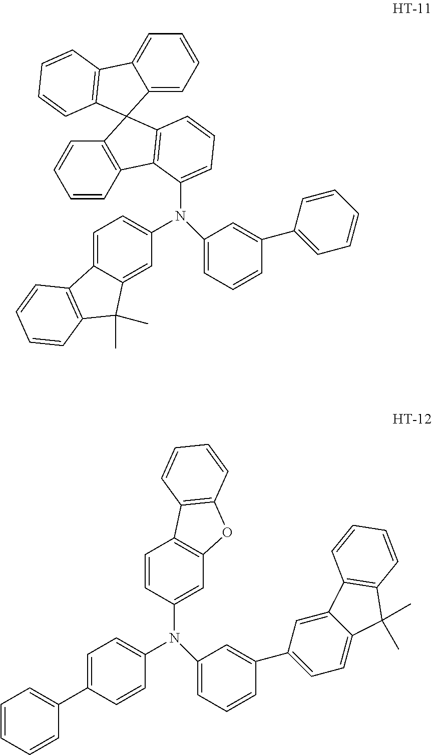 [SMILES: CC1(C)c2ccccc2-c2ccc(N(c3cccc(-c4ccccc4)c3)c3cccc4c3-c3ccccc3C43c4ccccc4-c4ccccc43)cc21 ; CC1(C)c2ccccc2-c2cc(-c3cccc(N(c4ccc(-c5ccccc5)cc4)c4ccc5c(c4)oc4ccccc45)c3)ccc21]

For example, the hole transport region 120 may include m-MTDATA (4,4′,4″-[tris(3-methylphenyl)phenylamino]triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), Spiro-TPD, Spiro-NPB, DNTPD (N¹,N^{1′}-([1,1′-biphenyl]-4,4′-diyl)bis(N¹-phenyl-N⁴,N⁴-di-m-tolylbenzene-1,4-diamine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), TCTA (4,4′,4″-tris(N-carbazolyl)triphenylamine), PANI/DBSA (polyaniline/dodecylbenzenesulfonic acid), PEDOT/PSS (poly(3,4-ethylenedioxythiophene)/poly(4-styrenesulfonate)), PANI/CSA (polyaniline/camphor sulfonic acid), PANI/PSS (polyaniline/poly(4-styrenesulfonate)), a phthalocyanine compound, a carbazole compound (N-phenylcarbazole, polyvinylcarbazole, or other carbazole compound), a fluorene compound, etc. These may be used alone or in a combination of two or more therefrom.

The above-described material may be included in at least one layer of the hole injection layer 122, the hole transport layer 124 and the electron blocking layer 126.

The hole transport region 120 may further include a charge generating material. A dopant material such as, for example, a p-dopant may be used as the charge generating material, and thus a conductivity of the hole transport region 120 may be improved.

For example, examples of the dopant materials include a halogenated metal compound such as, for example, LiF, NaCl, CsF, RbCl, RbI, CuI, and KI; a quinone derivative such as, for example, TCNQ (tetracyanoquinodimethane), F4-TCNQ (2,3,5,6-tetrafluoro-7,7,8,8-tetracyanoquinodimethane), or the like; a cyano-containing compound such as, for example, HATCN (dipyrazino[2,3-f: 2′,3′-h]quinoxaline-2,3,6,7,10,11-hexacarbonitrile), NDP9 (4-[[2,3-bis[cyano-(4-cyano-2,3,5,6-tetrafluorophenyl)methylidene]cyclopropylidene]-cyanomethyl]-2,3,5,6-tetrafluorobenzonitrile), or the like; a W oxide; a Mo oxide, etc. These may be used alone or in a combination of two or more therefrom.

A thickness of the hole transport region 120 may range from about 100 Å to about 10,000 Å, e.g., from about 100 Å to about 1,500 Å.

When the hole transport region 120 includes the hole injection layer 122 and the hole transport layer 124, a thickness of the hole injection layer 122 may range from about 100 Å to about 9,000 Å, from about 100 Å to about 3,000 Å, or from about 100 Å to about 1,000 Å. A thickness of the hole transport layer 124 may range from about 50 Å to about 2,000 Å, from about 100 Å to about 1,500 Å, from about 100 Å to about 1,000 Å, or from about 100 Å to about 600 Å.

In the above thickness range, hole transport properties may be enhanced even at a low voltage operation, and a life-span of the device may be further improved.

Each layer of the hole transport region 120 may be formed by a process such as, for example, a vacuum deposition, a spin coating, an inkjet printing, a laser printing, a casting, a laser thermal transfer, or other process supportive of forming the layer.

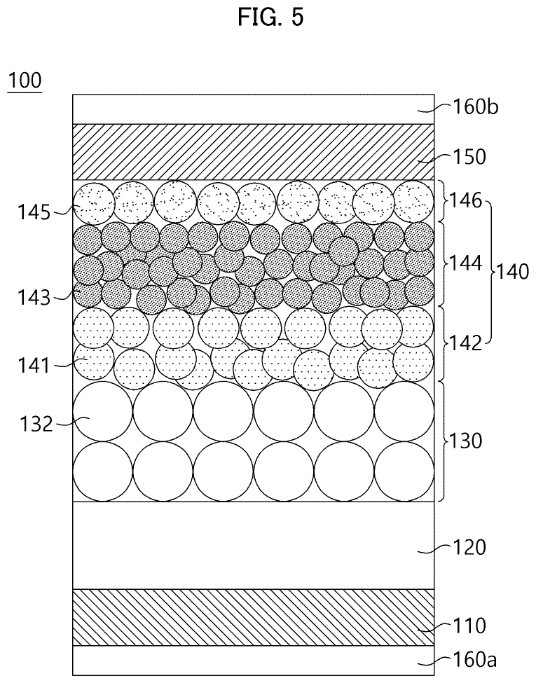

FIG. 5 is a schematic cross-sectional view illustrating a light-emitting device according to embodiments.

Referring to FIG. 5, a first capping layer 160a may be formed on an outer surface of the first electrode 110. In some embodiments, a second capping layer 160b may be formed on an outer surface of the second electrode 150.

A refractive index of the first capping layer 160a and/or the second capping layer 160b may be about 1.6 or more. For example, the refractive index of the first capping layer 160a and/or the second capping layer 160b may be about 1.6 or more for a light in a wavelength range of 550 nm to 660 nm.

The first capping layer 160a and the second capping layer 160b may each be formed as an organic capping layer including an organic material, an inorganic capping layer including an inorganic material, or an organic-inorganic hybrid capping layer including both the organic and inorganic materials.

In some embodiments, the first capping layer 160a and/or the second capping layer 160b may include a carbocyclic compound, a heterocyclic compound, an amine group-containing compound, a phosphine derivative, a phthalocyanine derivative, a naphthalocyanine derivative, an alkaline metal complex, an alkaline earth metal complex, etc. These may be used alone or in a combination with two or more therefrom.

In an embodiment, the first capping layer 160a and/or the second capping layer 160b may include the amine group-containing compound.

The above-described light-emitting device 100 may be applied to a display device or an electronic device, and may be provided as a light-emitting portion or a light-emitting unit of the display device or the electronic device.

The display device or the electronic device may include a billboard, a guide-sign display board, a light source/lighting device, a personal computer such as, for example, a laptop or a desktop computer, a mobile phone, an electronic book, an electronic dictionary, an electronic notebook, various sensors, a diagnostic device, various display units of transportation means (automobile, aircraft, ship, train, or the like).

In example embodiments, the light-emitting device 100 may be applied to an organic light emitting diode (OLED) display device or a quantum dot (QD)-OLED display device.

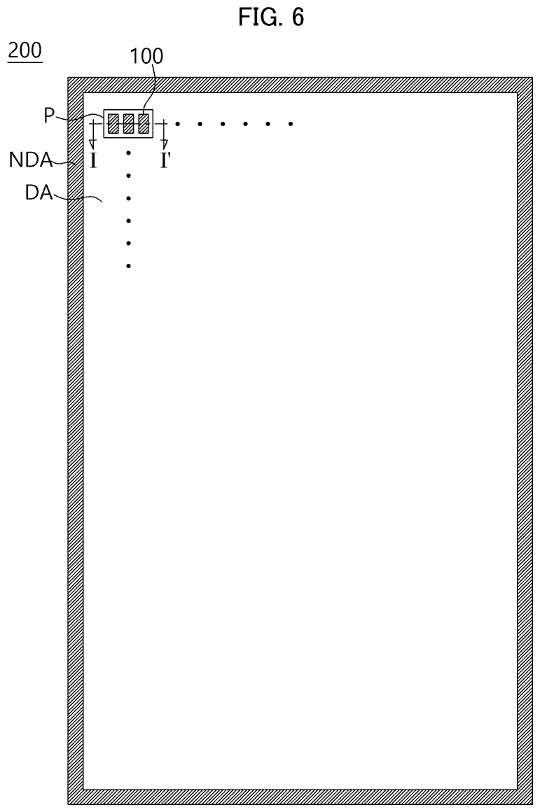

FIG. 6 is a schematic plan view illustrating a display device according to embodiments.

Referring to FIG. 6, a display device 200 may include a display area DA and a non-display area NDA.

For example, a pixel P may be disposed in the display area DA, and the pixel P may not be disposed in the non-display area NDA.

The pixel P may include at least one light-emitting device 100 as described herein. For example, a plurality of the light-emitting devices 100 may be included in one pixel P.

In some embodiments, the non-display area NDA may be disposed along a periphery of the display area DA. Although FIG. 6 illustrates that the non-display area NDA surrounds the display area DA, the present invention is not limited thereto. For example, the non-display area NDA may be omitted or may be adjacent to a single side of the display area DA.

The display device 200 may include a flat display, a curved display, a three-dimensional display, or the like.

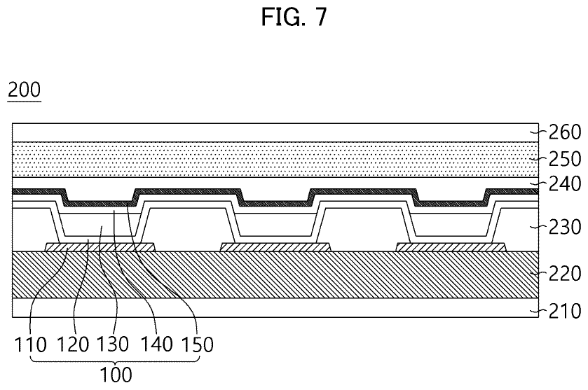

FIG. 7 is a schematic cross-sectional view illustrating a display device according to embodiments. For example, FIG. 7 is a cross-sectional view taken along a line I-I′ of FIG. 6 in a thickness direction. Although the electron transport region 140 is illustrated as a single layer in FIG. 7, the electron transport region 140 may have a multi-layered structure as described herein.

Referring to FIG. 7, the display device 200 may include a circuit layer 220 disposed on the base substrate 210, and the light-emitting device 100 disposed on the circuit layer 220. For example, the display device 200 may include a plurality of the light-emitting devices 100.

The base substrate 210 may serve as a supporting substrate or a back-plane substrate of an image display device. A glass substrate or a plastic substrate may be used as the base substrate 210.

In some embodiments, the base substrate 210 may include a polymer material having transparent and flexible properties. In this case, the display device 200 may be used in a transparent flexible display device. For example, the base substrate 210 may include a polymer material such as, for example, polyimide, polysiloxane, an epoxy resin, an acrylic resin, polyester, or the like. In an embodiment, the base substrate 210 may include polyimide.

In an embodiment, a surface of the base substrate 210 may be pretreated by a chemical treatment using a chemical such as, for example, a silane coupling agent, a plasma treatment, an ion plating treatment, a sputtering treatment, a gas phase reaction treatment, a vacuum deposition treatment, or the like.

The circuit layer 220 may include transistors. The circuit layer 220 may include wiring layers and insulating layers forming a thin film transistor array (TFT-Array).

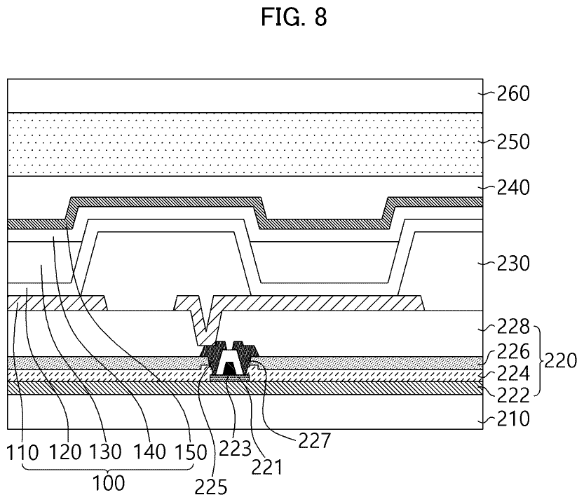

FIG. 8 is a schematic cross-sectional view illustrating a display device according to embodiments. For example, FIG. 8 is a partially enlarged cross-sectional view of the display device 200 for describing a detailed structure of the circuit layer 220.

Referring to FIG. 8, the circuit layer 220 may include a buffer layer 222 disposed on a top surface of the base substrate 210. Moisture penetrating through the base substrate 210 may be blocked by the buffer layer 222, and diffusion of impurities between the base substrate 210 and structures disposed on the base substrate 210 may be blocked.

The buffer layer 222 may include, e.g., silicon oxide, silicon nitride or silicon oxynitride. These may be used alone or in a combination thereof. In some embodiments, the buffer layer 222 may have a stacked structure including a silicon oxide layer and a silicon nitride layer.

An active pattern 221 may be disposed on the buffer layer 222. The active pattern 221 may be repeatedly formed for each pixel. The active pattern 221 may include a silicon compound such as, for example, polysilicon. A p-type dopant or an n-type dopant may be doped in a partial region of the active pattern 221.

In some embodiments, the active pattern 221 may include an oxide semiconductor such as, for example, indium gallium zinc oxide (IGZO), zinc tin oxide (ZTO), or ITZO.

A gate insulation layer 224 may be formed on the buffer layer 222 and cover the active pattern 221. For example, the gate insulation layer 224 may include silicon oxide, silicon nitride or silicon oxynitride, and may have a stacked structure including a silicon oxide layer and a silicon nitride layer.

A gate electrode 223 may be disposed on the gate insulation layer 224. In an embodiment, the gate electrode 223 may have a plate shape overlapping a region of the active pattern 221.

In an embodiment, the gate electrode 223 may include a metal such as, for example, Ag, Mg, Al, W, Cu, Ni, Cr, Mo, Ti, Pt, Ta, Nd, Sc, etc., an alloy thereof, or a nitride thereof.

An insulating interlayer 226 covering the gate electrode 223 may be formed on the gate insulation layer 224. The insulating interlayer 226 may include silicon oxide, silicon nitride and/or silicon oxynitride, and may include a stacked structure thereof.

A drain electrode 225 and a source electrode 227 may be formed on the gate insulation layer 224. Each of the drain electrode 225 and the source electrode 227 may penetrate through the insulating interlayer 226 and the gate insulation layer 224 to be in contact with the active pattern 221.

In an embodiment, the drain electrode 225 and the source electrode 227 may include a metal such as, for example, Ag, Mg, Al, W, Cu, N¹, Cr, Mo, Ti, Pt, Ta, Nd or Sc, an alloy thereof, or a nitride thereof.

For example, a structure including the active pattern 221, the gate electrode 223, the drain electrode 225, and the source electrode 227 may be provided as the transistor.

In some embodiments, the transistor may be connected to the first electrode 110 of the light-emitting device 100.

A via insulation layer 228 may be formed on the insulating interlayer 226 and cover the drain electrode 225 and the source electrode 227.

The via insulation layer 228 may accommodate a via structure electrically connecting the first electrode 110 to the drain electrode 225. In some embodiments, the via insulation layer 228 may serve as a planarization layer of the circuit layer 220. The via insulation layer 228 may include an organic material such as, for example, polyimide, an epoxy resin, an acrylic resin, or polyester.

The above-described light-emitting devices 100 may be disposed on the via insulation layer 228.

The first electrode 110 may be electrically connected to the drain electrode 225 or the source electrode 227 included in the circuit layer 220 through the via structure. As illustrated in FIG. 8, the first electrode 110 may be in contact with or connected to the drain electrode 225 to serve as a pixel electrode patterned for each light-emitting region or pixel region.

The pixel defining layer 230 may be formed on the via insulation layer 228 to define the light-emitting region or the pixel region. A blue light-emitting region, a red light-emitting region, and a green light-emitting region may be separated and defined by the pixel defining layer 230, and the light-emitting devices 100 may include a blue light-emitting device, a red light-emitting device, and a green light-emitting device.

The pixel defining layer 230 may partially cover the first electrode 110 of each light emitting region.

As illustrated in FIG. 7, the hole transport region 120 and the electron transport region 140 may be commonly and continuously formed on the pixel defining layer 230 and a plurality of the first electrodes 110. The emission layer 130 may be formed in the form of an island pattern separated for each light-emitting region or pixel region, and may be defined by the pixel defining layer 230.

In some embodiments, the emission layer 130 may also be commonly and continuously formed over a plurality of the light-emitting regions or the pixel regions.

In some embodiments, the hole transport region 120, the emission layer 130 and the electron transport region 140 may all be separated and selectively formed for each light-emitting region or the pixel region.

The second electrode 150 may serve as a common electrode continuously formed over a plurality of the light-emitting regions or the pixel regions.

The encapsulation layer 240 may be disposed on the pixel defining layer 230 and the light-emitting devices 100 to protect the light-emitting devices 100 from moisture or oxygen. The encapsulation layer 240 may be formed as a single-layered or multi-layered thin film encapsulation (TFE).

The encapsulation layer 240 may include an inorganic layer including silicon nitride (SiNx), silicon oxide (SiOx), indium tin oxide, indium zinc oxide or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)) or any combination thereof; or a combination of the organic layer and the inorganic layer.

The display device may further include a functional layer 250 disposed on the encapsulation layer 240. The functional layer 250 may include a sensor layer such as, for example, a touch sensor layer; or an optical layer such as, for example, a polarizing layer, a color conversion layer or a color filter layer.

In an embodiment, a window 260 may be disposed on the functional layer 250. The window 260 may provide a base surface on which the functional layer 250 is disposed. The window 260 may include a polymer material such as, for example, polyimide, polysiloxane, an epoxy resin, an acrylic resin or polyester, or may include a glass substrate or a metal substrate.

In some embodiments, the display device 200 may include a gate driver region. The gate driver region may be located on a lateral portion of the display device 200.

A scan line may extend from the gate driver region, and a data line and a power line may extend while crossing the scan line. For example, the data line and the power line may extend to be perpendicular to the scan line.

In an embodiment, a plurality of the scan lines and a plurality of the data lines may intersect each other. Each pixel or light-emitting device 100 may be connected to the scan line, the data line, and the power line.

The scan line may be electrically connected to the gate electrode 223. For example, the gate electrode 223 may protrude or extend from the scan line. The data line and/or the power line may be electrically connected to the source electrode 227.

In some embodiments, one end portion of the display device 200 may be electrically connected to a printed circuit board (PCB).

In an embodiment, a driving signal/driving voltage of the display device 200 may be supplied from the printed circuit board. The driving voltage may be transferred to each of the light-emitting devices 100 or the pixels P through the power line.

In an embodiment, the printed circuit board may include a data driving circuit. The data signal may be transmitted to the data line through the data driving circuit, and thus the data signal may be supplied to each of the light-emitting devices 100 or the pixels.

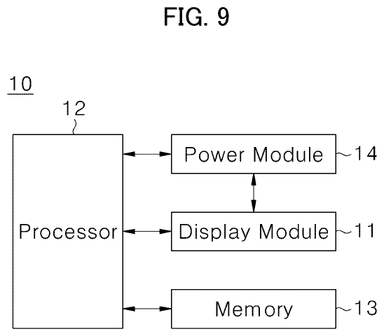

FIG. 9 is a block diagram of an electronic device in accordance with an embodiment.

Referring to FIG. 9, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. In an example in which the processor 12 executes an application stored in the memory 13, an image data signal and/or an input control signal may be transmitted to the display module 11, and the display module 11 may process the received signal and output image information through a display screen.

The power module 14 may include a power supply module such as, for example, a power adapter or a battery device, and a power conversion module that converts a power supplied by the power supply module to a generate power associated with powering the operation of the electronic device 10.

At least one of components of the electronic device 10 as described herein may be included in the display device according to the above-described embodiments. In some aspects, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

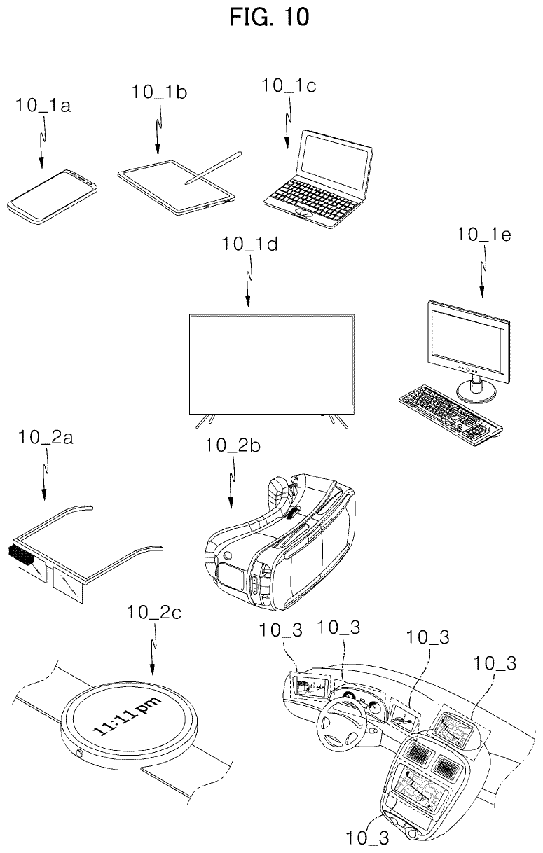

FIG. 10 is a schematic diagram of an electronic device in accordance with various embodiments.

Referring to FIG. 10, non-limiting examples of various electronic devices to which the display device according to the above-described embodiments is applied include an electronic device for displaying an image such as, for example, a smartphone 10_1a, a tablet PC 10_1b, a laptop 10_1c, a TV 10_1d, a desk monitor 10_1e, and the like; a wearable electronic device including a display module such as, for example, smart glasses 10_2a, a head mounted display 10_2b, a smart watch 10_2c, and the like; a vehicle electronic device 10_3 including a display module such as, for example, a center information display (CID) disposed at a vehicle instrument panel, a center fascia, a dashboard, or other portion of the vehicle, a room mirror display, and the like. The electronic device may include a virtual reality glass or an augmented reality glass.

Hereinafter, experimental examples including examples and comparative examples are provided to enhance understanding of the present disclosure, but these are provided as non-limiting examples, and are not to be interpreted as limiting the scope of the attached claims. It is clear to those skilled in the art that various changes and modifications to disclosed examples can be made within the scope of the present disclosure and the technical idea.

Embodiments supported by the present disclosure support methods and processes for fabricating a light-emitting device and a display device in accordance with at least the examples described with reference to FIG. 7, FIG. 8, and the experimental examples described herein. Descriptions herein that an element (e.g., a layer, an emission layer, an electron transport layer, an electrode, or other layers or components) “may be disposed,” “may be formed,” and the like support methods, processes, and techniques for disposing the element, forming the element, and the like in accordance with example aspects described herein.

### Example 1

An ITO substrate having a thickness of 150 nm (Corning Co.) as an anode (a first electrode) was ultrasonically cleaned for 5 minutes each using isopropyl alcohol and pure water, irradiated with ultraviolet ray and exposed to ozone for 30 minutes, and then the substrate was installed in an inkjet printing device.

2-TNATA (4,4′,4″-tris[N(2-naphthyl)-N-phenylamino]-triphenylamine) was inkjet-printed on the anode to form a hole injection layer having a thickness of 60 nm.

A hole transport layer having a thickness of 30 nm was formed by inkjet-printing TFB (poly[(9,9-dioctylfluorenyl-2,7-diyl)-co-(4,4′-(N-(4-sec-butylphenyl)diphenylamine)]) as a hole transport material on the hole injection layer.

An emission layer having a thickness of 25 nm was formed by inkjet-printing quantum dots having an average particle diameter D50 of 10 nm on the hole transport layer.

Particles including a ZnSeTe-containing core, a ZnSe and ZnS-containing shell disposed on the core with an oleic acid ligand bound to a surface of the shell were used as the quantum dots.

ZnMgO particles having a D50 of 8 nm as first particles were inkjet-printed on the emission layer to form a first electron transport layer having a thickness of 15 nm.

ZnMgO particles having a D50 of 3 nm as second particles were inkjet-printed on the first electron transport layer to form a second electron transport layer having a thickness of 25 nm.

LiF was inkjet-printed on the second electron transport layer to form an electron injection layer having a thickness of 1 nm.

Al was ink-jet-printed on the electron injection layer to form a cathode (a second electrode) having a thickness of 100 nm to obtain a light-emitting device.

### Example 2

A light-emitting device was manufactured by the same method as that in Example 1, except that ZnMgO particles having a D50 of 8 nm were inkjet-printed on the second electron transport layer to form a third electron transport layer having a thickness of 10 nm, and the electron injection layer and the cathode were formed on the third electron transport layer.

### Examples 3 to 20

Light-emitting devices were manufactured by the same method as that in Example 2, except that D50s of the quantum dots, the first particles, the second particles and the third particles were changed as illustrated in Table 1 below.

### Comparative Example 1

A light-emitting device was manufactured by the same method as that in Example 1, except that ZnMgO particles having a D50 of 3 nm were inkjet-printed on the emission layer instead of the first electron transport layer and the second electron transport layer to form a single-layered electron transport layer having a thickness of 40 nm.

### Comparative Example 2

A light-emitting device was manufactured by the same method as that in Example 1, except that ZnMgO particles having a D50 of 8 nm were inkjet-printed on the emission layer instead of the first electron transport layer and the second electron transport layer to form a single-layered electron transport layer having a thickness of 40 nm.

### Comparative Example 3

A light-emitting device was manufactured by the same method as that in Example 1, except that the D50 of ZnMgO particles included in the first electron transport layer was changed to 3 nm and the D50 of ZnMgO particles included in the second electron transport layer was changed to 8 nm.

### Experimental Example

### (1) Measurement of Average Particle Diameter (D50)

The light-emitting devices of the above-described Examples and Comparative Examples were decomposed, and the D50 of the particles included in each layer was measured using a particle size analyzer (PSA) (Mastersizer 3000, Malvern Panalytic Co., Ltd.).

### (2) Evaluation on Luminous Efficiency

A luminous efficiency at a current density of 50 mA/cm² was measured for each light-emitting devices of the above-described Examples and Comparative Examples. The luminous efficiency was evaluated using a current voltmeter (Kethley SMU 236) and a luminance meter (PR650).

The luminous efficiency was evaluated using a ratio of the luminous efficiency of Examples and Comparative Examples relative to the luminous efficiency of Comparative Example 1 as follows.
⊚: The ratio of the luminous efficiency relative to the luminous efficiency of Comparative Example 1 exceeded 1.15
◯: The ratio of the luminous efficiency relative to the luminous efficiency of Comparative Example 1 ranged from 1.1 to 1.15
Δ: The ratio of the luminous efficiency relative to the luminous efficiency of Comparative Example 1 was greater than or equal to 1.05 and less than 1.1.
X: The ratio of the luminous efficiency relative to the luminous efficiency of Comparative Example 1 was 1.0 or less.

### (3) Evaluation on Life-Span Property

For each light-emitting device of the above-described Examples and Comparative Examples, a luminance half-life at a current density of 100 mA/cm² was measured. The luminance half-life was evaluated as a time until the luminance became half of an initial luminance.

The luminance half-life was measured using a current voltmeter (Kethley SMU 236) and a luminance meter (PR650).

A life-span property was evaluated using a ratio of the luminance half-life of Examples and Comparative Examples relative to the luminance half-life of Comparative Example 1 as follows.
⊚: The ratio of the luminance half-life relative to the luminance half-life of Comparative Example 1 exceeded 1.2.
◯: The ratio of the luminance half-life relative to the luminance half-life of Comparative Example 1 ranged from 1.1 to 1.2.
Δ: The ratio of the luminance half-life relative to the luminance half-life of Comparative Example 1 was greater than or equal to 1.05 and less than 1.1.
X: The ratio of the luminance half-life relative to the luminance half-life of Comparative Example 1 was 1.0 or less.

The measurement and evaluation results are illustrated in Table 1 below.

In Comparative Examples 1 and 2, “single layer (D50: x nm)” refers to a single-layered electron transport layer where ZnMgO particles having a D50 of x nm were used.

TABLE 1

| | | | | | | life- |
|---|---|---|---|---|---|---|
| | D50 (nm) | | | | luminous | span |
| | first | second | third | quantum | efficien- | prop- |
| | particle | particle | particle | dots | cy | erty |
| Example 1 | 8 | 3 | — | 10 | Δ | ◯ |
| Example 2 | 8 | 3 | 8 | 10 | ⊚ | ⊚ |
| Example 3 | 5 | 3 | 8 | 10 | ⊚ | ◯ |
| Example 4 | 10 | 3 | 8 | 10 | ⊚ | ⊚ |
| Example 5 | 20 | 3 | 8 | 10 | ⊚ | ◯ |
| Example 6 | 4 | 3 | 8 | 10 | ◯ | Δ |
| Example 7 | 21 | 3 | 8 | 10 | ◯ | Δ |
| Example 8 | 8 | 2 | 8 | 10 | ⊚ | ⊚ |
| Example 9 | 8 | 4 | 8 | 10 | ⊚ | ⊚ |
| Example 10 | 8 | 1 | 8 | 10 | Δ | Δ |
| Example 11 | 8 | 5 | 8 | 10 | Δ | ◯ |
| Example 12 | 8 | 3 | 5 | 10 | ◯ | ⊚ |
| Example 13 | 8 | 3 | 10 | 10 | ⊚ | ⊚ |
| Example 14 | 8 | 3 | 20 | 10 | ◯ | ⊚ |
| Example 15 | 8 | 3 | 4 | 10 | Δ | ◯ |
| Example 16 | 8 | 3 | 21 | 10 | Δ | ◯ |
| Example 17 | 8 | 3 | 8 | 5 | ⊚ | ◯ |
| Example 18 | 8 | 3 | 8 | 15 | ◯ | ◯ |
| Example 19 | 8 | 3 | 8 | 3 | ◯ | Δ |
| Example 20 | 8 | 3 | 8 | 16 | ◯ | Δ |
| Comparative | single layer (D50: 3 nm) | | | 10 | X | X |
| Example 1 | | | | | | |
| Comparative | single layer (D50: 8 nm) | | | 10 | X | Δ |
| Example 2 | | | | | | |
| Comparative | 3 | 8 | — | 10 | Δ | X |
| Example 3 | | | | | | |

In Examples where multiple electron transport layers were included on the emission layer and the particles having relatively large D50s were included in the electron transport layer adjacent to the emission layer, the luminous efficiency and the life-span property were improved compared to those from Comparative Examples.

In Example 6 where the D50 of the first particles was less than 5 nm, the life-span property was relatively lowered compared to life-span properties from other Examples.

In Example 7 where the D50 of the first particles was greater than 20 nm, the life-span property was relatively lowered compared to life-span properties from other Examples.

In Example 10 where the D50 of the second particles was less than 2 nm, the luminous efficiency and the life-span property were relatively lowered compared to those from other Examples.

In Example 11 where the D50 of the second particles was greater than 4 nm, the luminous efficiency was relatively lowered compared to luminous efficiencies from other Examples.

In Example 15 where the D50 of the third particles was less than 5 nm, the luminous efficiency was relatively lowered compared to luminous efficiencies from other Examples.

In Example 16 where the D50 of the third particles exceeded 20 nm, the luminous efficiency was relatively lowered compared to other Examples.

In Example 19 where the D50 of the quantum dots was less than 5 nm, the life-span property was relatively lowered compared to the life-span properties from other Examples.

In Example 20 where the D50 of the quantum dots exceeded 15 nm, the life-span property was relatively lowered compared to life-span properties from other Examples.

What is claimed is:

1. Alight-emitting device, comprising:
a first electrode;
a second electrode;
an emission layer between the first electrode and the second electrode; and
an electron transport region between the emission layer and the second electrode, wherein the electron transport region comprises:
a first electron transport layer on the emission layer, the first electron transport layer comprising first particles; and
a second electron transport layer on the first electron transport layer, the second electron transport layer comprising second particles having an average particle diameter smaller than an average particle diameter of the first particles.

2. The light-emitting device of claim 1, wherein the average particle diameter of the first particles ranges from 5 nm to 20 nm.

3. The light-emitting device of claim 1, wherein the average particle diameter of the first particles ranges from 5 nm to 10 nm.

4. The light-emitting device of claim 1, wherein the average particle diameter of the second particles ranges from 2 nm to 4 nm.

5. The light-emitting device of claim 1, wherein the average particle diameter of the second particles ranges from 3 nm to 4 nm.

6. The light-emitting device of claim 1, wherein:
the electron transport region further comprises a third electron transport layer on the second electron transport layer, and
the third electron transport layer comprises third particles having an average particle diameter greater than the average particle diameter of the second particles.

7. The light-emitting device of claim 6, wherein the first particles, the second particles and the third particles comprise the same material.

8. The light-emitting device of claim 6, wherein the average particle diameter of the third particles ranges from 5 nm to 20 nm.

9. The light-emitting device of claim 1, wherein the emission layer comprises quantum dots.

10. The light-emitting device of claim 9, wherein an average particle diameter of the quantum dots ranges from 5 nm to 15 nm.

11. The light-emitting device of claim 9, wherein an average particle diameter of the quantum dots is equal to or less than the average particle diameter of the first particles.

12. The light-emitting device of claim 1, wherein the electron transport region further comprises an electron injection layer between the second electron transport layer and the second electrode.

13. The light-emitting device of claim 1, further comprising a hole transport region between the first electrode and the emission layer.

14. The light-emitting device of claim 13, wherein the hole transport region comprises:
a hole injection layer on the first electrode, and
a hole transport layer on the hole injection layer.

15. The light-emitting device of claim 1, wherein the first particles and the second particles each comprise at least one selected from the group consisting of ZnMgO, Li₂O, BaO, LiF, NaCl, CsF, RbCl, RbI, CuI, KI, a metal acetate, a metal benzoate, an anthracene compound, Alq3 (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), Bebq2 (bis(10-hydroxybenzo[h]quinolinato)beryllium), ADN (9,10-di(naphthalene-2-yl)anthracene) and BmPyPhB (1,3-bis[3,5-di(pyridin-3-yl)phenyl]benzene).

16. A display device, comprising:
a base substrate;
a circuit layer on the base substrate; and
a light-emitting device electrically connected to the circuit layer,
wherein the light-emitting device comprises:
a first electrode;
a second electrode;
an emission layer between the first electrode and the second electrode; and
an electron transport region between the emission layer and the second electrode,
wherein the electron transport region comprises:
a first electron transport layer on the emission, the first electron transport layer comprising first particles; and
a second electron transport layer on the first electron transport layer, the second electron transport layer comprising second particles, the second particles having an average particle diameter smaller than an average particle diameter of the first particles.

17. The display device of claim 16, wherein the emission layer comprises quantum dots, and the circuit layer comprises a transistor connected to the first electrode of the light-emitting device.

18. An electronic device, comprising:
the display device of claim 16;
a memory; and
a processor for executing data comprised in the memory associated with controlling an operation of the display device.

19. A method of fabricating a light-emitting device, comprising:
forming an emission layer on a first electrode;
forming a first electron transport layer comprising first particles on the emission layer by an inkjet printing;
forming a second electron transport layer on the first electron transport layer by an inkjet printing, wherein the second electron transport layer comprises second particles that have an average particle diameter smaller than an average particle diameter of the first particles; and
forming a second electrode on the second electron transport layer.

20. The method of claim 19, further comprising forming a third electron transport layer between the second electron transport layer and the second electrode, wherein the third electron transport layer comprises third particles that have an average particle diameter greater than the average particle diameter of the second particles.
